(19) United States
(12) Patent Application Publication
(10) Pub. No.: US 2008/0253104 A1
(43) Pub. Date: Oct. 16, 2008

(54) LEAD FRAME, MOLDING DIE, AND MOLDING METHOD

(75) Inventor: Tadahisa Inui, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 12/045,805

(22) Filed: Mar. 11, 2008

(30) Foreign Application Priority Data
Apr. 10, 2007 (JP) 2007-102278

(51) Int. Cl. H05K 7/20; B29C 70/72; B29C 33/00

(52) U.S. Cl. 361/813; 425/451.9; 264/241

(57) ABSTRACT

In a lead frame (36), inner leads (4), the terminal ends of support leads (2), and a die pad (3) are disposed in a molding area (11) molded with a molding resin (13) and a frame (1), the leading ends of the support leads (2), outer leads (5), and tie bars (6) are disposed outside the molding area (11). In the frame (1), slits (16) are formed by cutting on both sides of corners (15) disposed on the extension lines of the leading ends of the support leads (2).

### FIELD OF THE INVENTION

The present invention relates to a lead frame used for, for example, a low-profile semiconductor device and so on, a molding die used for molding the lead frame with resin when manufacturing a low-profile semiconductor device, and a molding method using the molding die.

### BACKGROUND OF THE INVENTION

In recent years, lead frames have varied in material and shape according to the uses. A generally known lead frame is shown in FIG. 25. FIG. 25 is a plan view showing a conventional lead frame 31. The lead frame 31 is made of a metal (plated copper, a copper alloy, 42 alloy, and so on). Further, the lead frame 31 includes a frame 1, a plurality of support leads 2 having leading ends (one ends) connected to the inner side of the frame 1, a die pad 3 connected to the terminal ends (the other ends) of the support leads 2, a plurality of inner leads 4 radially arranged at a predetermined spacing from the die pad 3, a plurality of outer leads 5 extended from the inner leads 4 and connected to the inner side of the frame 1, and tie bars 6 disposed on the boundaries of the inner leads 4 and the outer leads 5 to connect the adjacent leads.

FIG. 26 is a perspective view partially disclosing the configuration of a semiconductor device 32 including the conventional lead frame 31. As shown in FIG. 26, the semiconductor device 32 is molded by fixing a semiconductor chip 7 on the die pad 3 with an adhesive 8, connecting a plurality of bonding pads 9 formed on a surface of the semiconductor chip 7 to the plurality of inner leads 4 via conductive bonding wires 10, and injecting a molding resin 13 such as an epoxy resin into a molding area 11. Thereafter, on the molded lead frame 31, the tie bars 6 and the frame 1 outside the molding area 11 are cut and the outer leads 5 protruding to the outside from the molding area 11 are worked according to a mounting pattern.

In the semiconductor device 32 using the lead frame 31 configured thus, as shown in FIG. 27, steps 14 are formed on the support leads 2 to equalize upper and lower resin thicknesses T on the semiconductor chip 7 and the die pad 3. Thus it is possible to prevent breaks on the bonding wires 10 or the exposure of the bonding wires 10, the semiconductor chip 7, and the die pad 3 from the molding area 11.

However, as the semiconductor device 32 is reduced in thickness, it is not possible to sufficiently prevent a die pad shift (a phenomenon in which the die pad moves) and the exposure of the bonding wires 10 only by the above-mentioned configuration.

FIG. 27 is a sectional view of a molding die 33 used when the molding resin 13 is injected into the molding area 11 of the semiconductor device 32 using the conventional lead frame 31 and then molding is performed.

As shown in FIG. 27, in the case where the steps 14 are formed on the support leads 2 to equalize the upper and lower resin thicknesses T on the die pad 3 and the semiconductor chip 7, the upper and lower resin thicknesses T on the semiconductor chip 7 and the die pad 3 can be equalized when a package and the lead frame 31 have large thicknesses. This configuration makes it possible to reduce a difference in pressure between the upper and lower portions of the molding area 11 where the molding resin 13 is injected from an injection portion 12. Thus as shown in FIG. 28, the degree (magnitude) of a die pad shift is not so large that the semiconductor chip 7, the die pad 3, and the bonding wires 10 are exposed from the molding area 11

However, as shown in FIG. 29, as the package and the lead frame 31 are reduced in thickness, the support leads 2 decrease in stiffness and the amount of die pad shift increases according to a reduction in the thickness of the lead frame 31. On the other hand, as the package is reduced in thickness, a tolerance for a die pad shift decreases. Consequently, the semiconductor chip 7, the die pad 3, and the bonding wires 10 are exposed to the outside from the molding area 11.

Therefore, it is necessary to attain another solution to reduce the amount of die pad shift as the package and the lead frame 31 are reduced in thickness.

Therefore, an object of the present invention is to provide a lead frame, a molding die, and a molding method which can reduce an amount of die pad shift.

### DISCLOSURE OF THE INVENTION

A first invention is a lead frame including:

a frame;

support leads having the leading ends connected to the inner side of the frame;

a die pad connected to the terminal ends of the support leads;

a plurality of inner leads radially arranged at a predetermined spacing from the die pad;

outer leads extended from the inner leads and connected to the inner side of the frame; and

tie bars disposed on the boundaries of the inner leads and the outer leads to connect the adjacent leads,

the lead frame having the inner leads, the terminal ends of the support leads, and the die pad in a molding areas and

the lead frame having the frame, the leading ends of the support leads, the outer leads, and the tie bars outside the molding area,

wherein the lead frame further includes slits formed on both sides of corners disposed on the extension lines of the leading ends of the support leads in the frame.

With this configuration, when the lead frame is clamped using a molding die to be molded with resin, the distortions of the support leads in the molding area are absorbed by the slits, so that an amount of die pad shift can be reduced.

According to a second invention, the lead frame further includes holes formed on the corners disposed on the extension lines of the leading ends of the support leads in the frame.

With this configuration, when the lead frame is clamped using a molding die to be molded with resin, the distortions of the support leads in the molding area are absorbed by the slits. Further, during the clamping, the positions of the holes on the corners are displaced to the outside along the lengths of the support leads. Thus the tensile force of the support leads is increased to have a larger bearing force, so that an amount of die pad shift can be reduced.

According to a third invention, the lead frame further includes notches extended from the slits and cut to the outside along the widths of the support leads.

With this configuration, when the lead frame is clamped using a molding die to be molded with resin, the distortions of the support leads in the molding area are absorbed by the slits. Further, during the clamping, the positions of the notches of the slits are displaced to the outside along the lengths of the support leads. Thus the tensile force of the support leads is increased to have a larger bearing force, so that an amount of die pad shift can be reduced.

A fourth invention includes a step formed on the support lead,

wherein the step of the support lead is larger in width than a part other than the step of the support lead.

With this configuration, the formation of the steps can substantially equalize upper and lower resin thicknesses on the die pad and a semiconductor chip mounted on the die pad. Further, the steps have large widths and thus even when a large tensile force is applied to the support leads, it is possible to prevent the deformation of the steps.

A fifth invention is a molding die used for clamping the lead frame according to the first invention and molding the lead frame with resin, the molding die including an upper die body and a lower die body, the upper and lower die bodies including: upper die and lower die first clamping portions for clamping the outer periphery of the molding area other than the support leads; and upper die and lower die second clamping portions for clamping the corners disposed on the extension lines of the leading ends of the support leads in the frame,

wherein the upper die first clamping portions are fixed on the upper die body,

the upper die second clamping portions are movable in the vertical direction relative to the upper die body,

the lower die first clamping portions are fixed on the lower die body, and

the lower die second clamping portions are movable in the vertical direction relative to the lower die body.

In this configuration, the outer periphery of the molding area other than the support leads of the lead frame is clamped by the upper die first clamping portions and the lower die first clamping portions At this moment, although the support leads are also expanded and distorted at a high temperature, the distortions of the support leads in the molding area are absorbed by the slits.

In this state, after a certain delay, the corners disposed on the extension lines of the leading ends of the support leads are clamped in the frame of the lead frame by the upper die second clamping portions and the lower die second clamping portions. Thus the corners can be clamped after the support leads are sufficiently expanded, thereby reducing the distortions of the support leads and an amount of die pad shift.

According to a sixth invention, the upper die second clamping portion and the lower die second clamping portion each have a bend forming portion for bending the corner.

With this configuration, when the corners of the support leads are clamped by the upper die second clamping portions and the lower die second clamping portions, the corners are bent by the bend forming portions. Thus the tensile force and the bearing force of the support leads are increased, so that an amount of die pad shift can be reduced.

A seventh invention is a molding die used for clamping the lead frame according to the second invention and molding the lead frame with resin, the molding die including an upper die body and a lower die body, the upper and lower die bodies including upper die and lower die clamping portions for clamping the outer periphery of the molding area other than the support leads;

wherein the upper die clamping portions are fixed on the upper die body,

the lower die clamping portions are fixed on the lower die body,

one of the upper die body and the lower die body includes die inserting members movable in the vertical direction,

the other die body includes die receiving members movable in the vertical direction,

the die inserting members have a convex portion,

the die receiving members have a concave portion,

the convex portions can be inserted into and removed from the holes on the corners and can be fit into and removed from the concave portions, and

the positions of the convex portions are, relative to the positions of the holes when the support leads are thermally expanded, displaced to the outside along the lengths of the support leads.

In this configuration, the outer periphery of the molding area other than the support leads of the lead frame is clamped by the upper die clamping portions and the lower die clamping portions. At this moment, although the support leads are also expanded and distorted at a high temperature, the distortions of the support leads in the molding area are absorbed by the slits.

In the clamping state, after a certain delay, the convex portions of the die inserting members are inserted into the holes on the corners of the lead frames and are fit into the concave portions of the die receiving members. At this point, relative to the positions of the holes when the support leads are thermally expanded, the positions of the convex portions are displaced to the outside along the lengths of the support leads, so that the positions of the holes are displaced to the outside. Thus the tensile force and the bearing force of the support leads are increased, so that an amount of die pad shift can be reduced.

An eighth invention is a molding die used for clamping the lead frame according to the third invention and molding the lead frame with resin, the molding die including an upper die body and a lower die body, the upper and lower die bodies including upper die and lower die clamping portions for clamping the outer periphery of the molding area other than the support leads;

wherein the upper die clamping portions are fixed on the upper die body,

the lower die clamping portions are fixed on the lower die body,

one of the upper die body and the lower die body includes die inserting members movable in the vertical direction,

the other die body includes die receiving members movable in the vertical direction,

the die inserting members have a pair of convex portions,

the die receiving members have a pair of concave portions,

the convex portions can be inserted into and removed from the notches of the slits and can be fit into and removed from the concave portions, and

the positions of the convex portions are, relative to the positions of the notches when the support leads are thermally expanded, displaced to the outside along the lengths of the support leads,

In this configuration, the outer periphery of the molding area other than the support leads of the lead frame is clamped by the upper die clamping portions and the lower die clamping portions. At this moment, although the support leads are also expanded and distorted at a high temperature, the distortions of the support leads in the molding area are absorbed by the slits.

In the clamping state, after a certain delay, the convex portions of the die inserting members are inserted into the notches of the slits of the lead frame and are fit into the concave portions of the die receiving members. At this point, relative to the positions of the notches when the support leads are thermally expanded, the positions of the convex portions are displaced to the outside along the lengths of the support leads, so that the positions of the notches are displaced to the outside. Thus the tensile force and the bearing force of the support leads are increased, so that an amount of die pad shift can be reduced.

A ninth invention is a molding method for molding the lead frame with resin by means of the molding die according to the fifth invention, including the steps of:

clamping the outer periphery of the molding area other than the support leads of the lead frame by means of the upper die first clamping portions and the lower die first clamping portions;

clamping, after a certain delay in this state, the corners disposed on the extension lines of the leading ends of the support leads in the frame of the lead frame, by means of the upper die second clamping portions and the lower die second clamping portions; and

injecting a molding resin into the molding area from an injection portion to mold the lead frame.

According to this method, when the outer periphery of the molding area other than the support leads is clamped by the upper die first clamping portions and the lower die first clamping portions, the distortions of the support leads in the molding area are absorbed by the slits.

In this state, after the certain delay, the corners of the support leads are clamped by the upper die second clamping portions and the lower die second clamping portions. Thus the corners can be clamped after the support leads are sufficiently expanded, thereby reducing the distortions of the support leads and an amount of die pad shift.

A tenth invention is a molding method for molding the lead frame with resin by means of the molding die according to the sixth invention, including the steps of:

clamping the outer periphery of the molding area other than the support leads of the lead frame by means of the upper die first clamping portions and the lower die first clamping portions;

clamping, after a certain delay in this state, the corners disposed on the extension lines of the leading ends of the support leads in the frame of the lead frame and bending the corners, by means of the upper die second clamping portions and the lower die second clamping portions; and

injecting a molding resin into the molding area from an injection portion to mold the lead frame.

According to this method, the tensile force and the bearing force of the support leads are increased, so that an amount of die pad shift can be reduced.

An eleventh invention is a molding method for molding the lead frame with resin by means of the molding die according to the seventh invention, including the steps of:

clamping the outer periphery of the molding area other than the support leads of the lead frame by means of the upper die clamping portions and the lower die clamping portions;

inserting, after a certain delay in this state, the convex portions of the die inserting members into the holes on the corners of the lead frame and fitting the convex portions into the concave portions of the die receiving members; and

injecting a molding resin into the molding area from an injection portion to mold the lead frame.

According to this method, when the outer periphery of the molding area other than the support leads is clamped by the upper die clamping portions and the lower die clamping portions, the distortions of the support leads in the molding area are absorbed by the slits.

In this state, after the certain delay, the convex portions of the die inserting members are inserted into the holes on the corners of the lead frame and are fit into the concave portions of the die receiving members, so that the positions of the holes on the corners are displaced to the outside. Thus the tensile force and the bearing force of the support leads are increased and an amount of die pad shift can be reduced.

According to a twelfth invention, the molding resin is injected and filled into the molding area, the molding resin in the molding area is polymerized to complete postcure, the convex portions of the die inserting members are removed from the concave portions of the die receiving members and are removed from the holes on the corners of the lead frame, the clamping of the upper die clamping portions and the lower die clamping portions is released, and then the molded lead frame is removed.

A thirteenth invention is a molding method for molding the lead frame with resin by means of the molding die according to the eighth invention, including the steps of:

clamping the outer periphery of the molding area other than the support leads of the lead frame by means of the upper die clamping portions and the lower die clamping portions;

inserting, after a certain delay in this state, the convex portions of the die inserting members into the notches of the slits of the lead frame and fitting the convex portions into the concave portions of the die receiving members; and

injecting a molding resin into the molding area from an injection portion to mold the lead frame.

According to this method, when the outer periphery of the molding area other than the support leads is clamped by the upper die clamping portions and the lower die clamping portions, the distortions of the support leads in the molding area are absorbed by the slits.

In the clamping state, after the certain delay, the convex portions of the die inserting members are inserted into the notches of the slits of the lead frame and are fit into the concave portions of the die receiving members, so that the positions of the notches are displaced to the outside. Thus the tensile force and the bearing force of the support leads are increased and an amount of die pad shift can be reduced.

In a fourteenth invention, the molding resin is injected and filled into the molding area, the molding resin in the molding area is polymerized to complete postcure, the convex portions of the die inserting members are removed from the concave portions of the die receiving members and are removed from the notches of the slits of the lead frame, the clamping of the upper die clamping portions and the lower die clamping portions is released, and then the molded lead frame is removed.

### BRIEF DESCRIPTION OF THE DRAWINGS

FIG. 1 is a plan view showing a lead frame according to a first embodiment of the present invention;

FIG. 2 is a perspective view partially disclosing the configuration of a semiconductor device using the lead frame according to the first embodiment of the present invention;

FIG. 3 is a sectional view showing a molding die used when the lead frame is molded with resin according to the first embodiment of the present invention;

FIG. 4 is an illustration taken along line G-G of FIG. 3;

FIG. 5 is an illustration taken along line H-H of FIG. 3;

FIG. 6 is a plan view showing that the lead frame is set on a lower die body of the molding die according to the first embodiment of the present invention;

FIG. 7 is a sectional view showing that the lead frame is clamped by the molding die according to the first embodiment of the present invention;

FIG. 8 is a sectional view showing a molding die according to a second embodiment of the present invention;

FIGS. 9A and 9B show a molding method of resin molding in which a lead frame is clamped using the molding die according to the second embodiment of the present invention;

FIGS. 10A and 10B show a molding method for resin molding in which the lead frame is clamped using the molding die according to the second embodiment of the present invention;

FIG. 11A is a plan view showing a lead frame according to a third embodiment of the present invention;

FIG. 11B is a sectional view taken along line A-B of FIG. 11A;

FIG. 12 is a plan view showing a lead frame according to a fourth embodiment of the present invention;

FIG. 13 is a sectional view showing a molding die used when the lead frame is molded with resin according to the fourth embodiment of the present invention;

FIG. 14A is a plan view showing the positional relationship between through holes of the lead frame and convex and concave portions of the molding die according to the fourth embodiment of the present invention;

FIG. 14B is a sectional view taken along line A-B of FIG. 14A;

FIG. 15 shows a molding method for molding the lead frame with resin according to the fourth embodiment of the present invention;

FIG. 16 shows a molding method for molding the lead frame with resin according to the fourth embodiment of the present invention;

FIG. 17 is a plan view showing a lead frame according to a fifth embodiment of the present invention;

FIG. 18 is a sectional view showing a molding die used when the lead frame is molded with resin according to the fifth embodiment of the present invention;

FIG. 19 is an illustration taken along line G-G of FIG. 18;

FIG. 20A is a front view showing an upper die inserting member of the molding die according to the fifth embodiment of the present invention;

FIG. 20B is an illustration taken along line J-J of FIG. 20A;

FIG. 20C is an illustration taken along line K-K of FIG. 20A;

FIG. 21A is a plan view showing the positional relationship between notches of the lead frame and convex and concave portions of the molding die according to the fifth embodiment of the present invention;

FIG. 21B is a sectional view taken along line A-B of FIG. 21A;

FIG. 22 is an illustration taken along line H-H of FIG. 18;

FIG. 23A is a front view showing a lower die receiving member of the molding die according to the fifth embodiment of the present invention;

FIG. 23B is an illustration taken along line J-J of FIG. 23A;

FIG. 23C is an illustration taken along line K-K of FIG. 23A;

FIG. 24 is a sectional view showing that the lead frame is clamped by the molding die according to the fifth embodiment of the present invention;

FIG. 25 is a plan view showing a conventional lead frame;

FIG. 26 is a perspective view partially disclosing the configuration of a semiconductor device using the conventional lead frame;

FIG. 27 is a sectional view showing that the conventional lead frame is clamped by a molding die;

FIG. 28 is a sectional view showing a process of injecting molding resin while clamping the conventional lead frame with the molding die; and

FIG. 29 is a sectional view showing a process of injecting molding resin while clamping, with the molding die, the lead frame for a conventional low-profile semiconductor device.

### DESCRIPTION OF THE EMBODIMENTS

The present invention will be specifically described below in accordance with the accompanying drawings. The same members as the prior art are indicated by the same reference numerals and the explanation thereof is omitted.

### First Embodiment

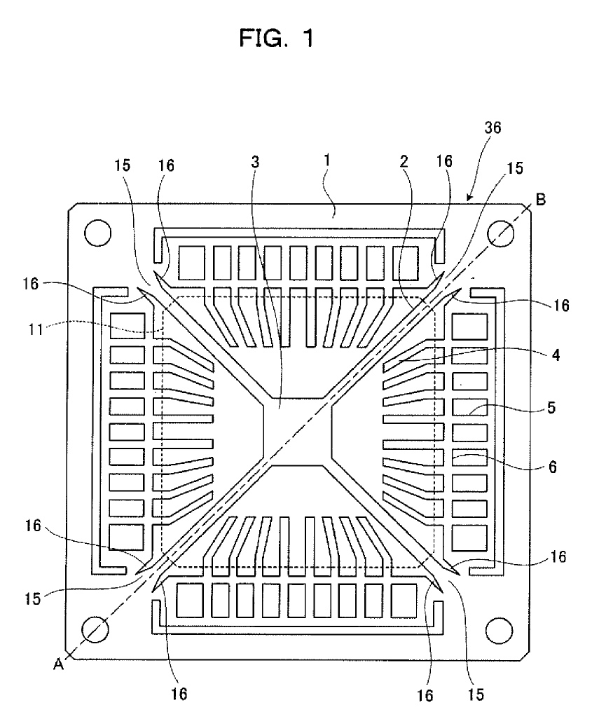

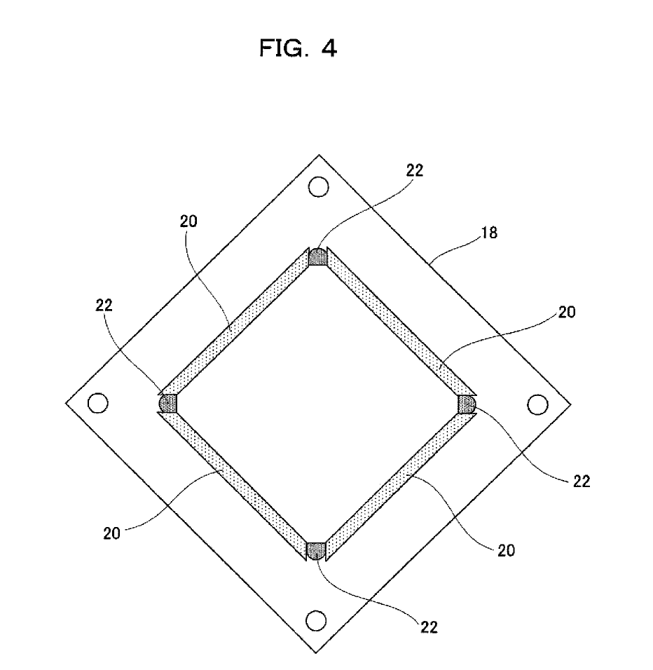

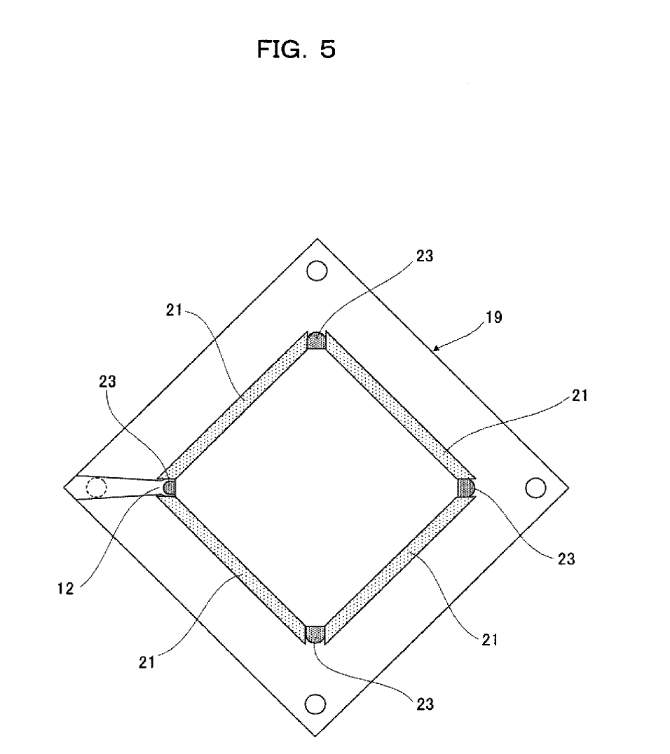

First, referring to FIGS. 1 to 7, a first embodiment will be described below.

FIG. 1 is a plan view showing a lead frame 36 of the first embodiment. The lead frame 36 includes a frame 1, a plurality of support leads 2 having leading ends (one ends) connected to the inner side of the frame 1, a die pad 3 connected to the terminal ends (the other ends) of the support leads 2, a plurality of inner leads 4 radially arranged at a predetermined spacing from the die pad 3, a plurality of outer leads 5 extended from the inner leads 4 and connected to the inner side of the frame 1, and tie bars 6 disposed on the boundaries of the inner leads 4 and the outer leads 5 to connect the adjacent leads.

In the lead frame 36, a molding area 11 molded with a molding resin 13 is set. The inner leads 4, the terminal ends (the other ends) of the support leads 2, and the die pad 3 are disposed inside the molding area 11. The frame 1, the leading ends (the one ends) of the support leads 2, the outer leads 5, and the tie bars 6 are disposed outside the molding area 11.

In the frame 1, slits 16 are formed on both sides of corners 15 disposed on the extension lines of the leading ends of support leads 2. The slits 16 are cut to the outside along the lengths of the support leads 2, and the frame 1 and the corners 15 are partially separated from each other by the slits 16.

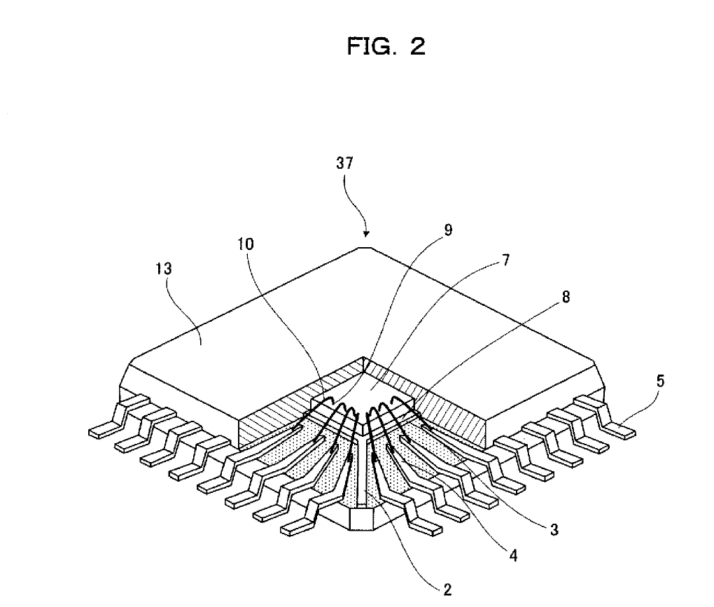

FIG. 2 is a perspective view partially disclosing the configuration of a semiconductor device 37 using the lead frame 36. The semiconductor device 37 is molded by fixing a semiconductor chip 7 on the die pad 3 with an adhesive 8, connecting a plurality of bonding pads 9 formed on a surface of the semiconductor chip 7 to the plurality of inner leads 4 via conductive bonding wires 10, and injecting the molding resin 13 such as an epoxy resin into the molding area 11.

Thereafter, on the molded lead frame 36, the tie bars 6 and the frame 1 outside the molding area 11 are cut and the outer leads 5 protruding to the outside from the molding area 11 are worked according to a mounting pattern.

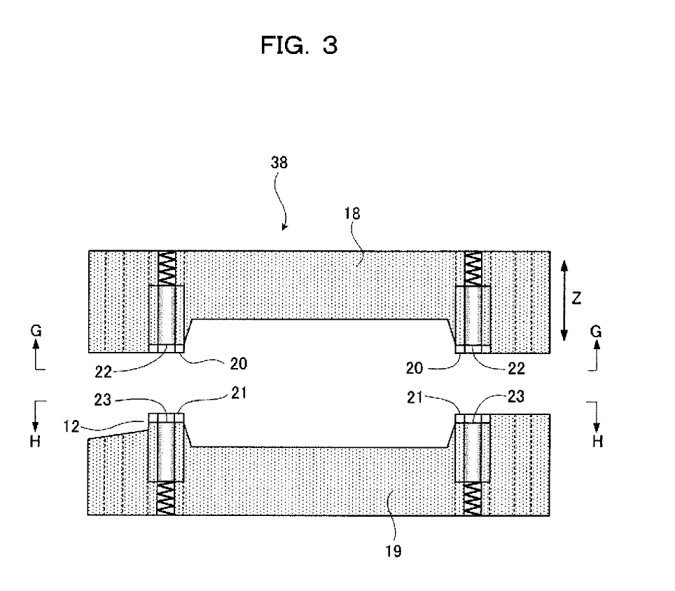

FIGS. 3 to 5 are sectional views showing a molding die 38 used when the molding resin 13 is injected to perform molding in a process of manufacturing the semiconductor device 37.

The molding die 38 is made up of an upper die body 18 and a lower die body 19 which are placed in a molding machine. The upper die body 18 can be moved in the Z axis direction (vertical direction) by an operating mechanism (not shown). The lower die body 19 is fixed on a reference position below the upper die body 18.

The upper die body 18 includes upper die first clamping portions 20 for clamping the outer periphery of the molding area 11 other than the support leads 2 and upper die second clamping portions 22 for clamping only the corners 15. The upper die first clamping portions 20 are fixed to the upper die body 18. The upper die second clamping portions 22 are built into the upper die body 18 so as to move in the vertical direction and are moved by a drive (not shown) in the vertical direction relative to the upper die body 18.

The lower die body 19 includes lower die first clamping portions 21 for clamping the outer periphery of the molding area 11 other than the support leads 2 and lower die second clamping portions 23 for clamping only the corners 15. The lower die first clamping portions 21 are fixed to the lower die body 19. The lower die second clamping portions 23 are built into the lower die body 19 so as to move in the vertical direction. The lower die second clamping portions 23 are moved by the drive (not shown) in the vertical direction relative to the lower die body 19.

The molding die 38 is heated by a heater and is kept at about 150° C. to 250° C.

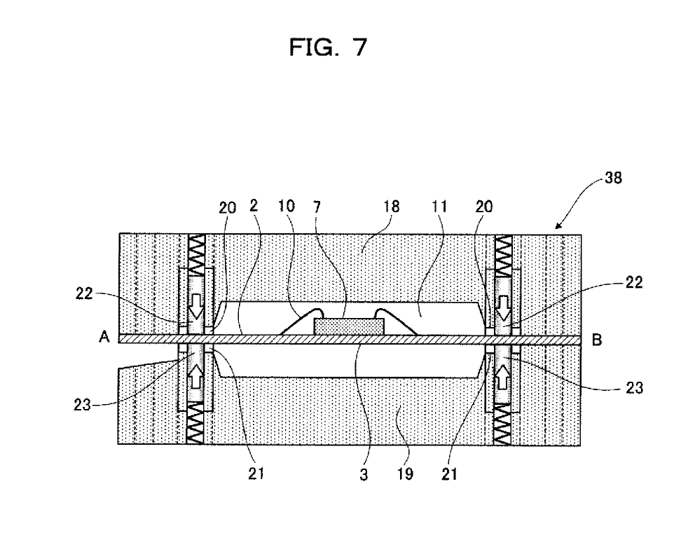

FIG. 7 is a sectional view showing a state in which the lead frame 36 is clamped by the upper die body 18 and the lower die body 19.

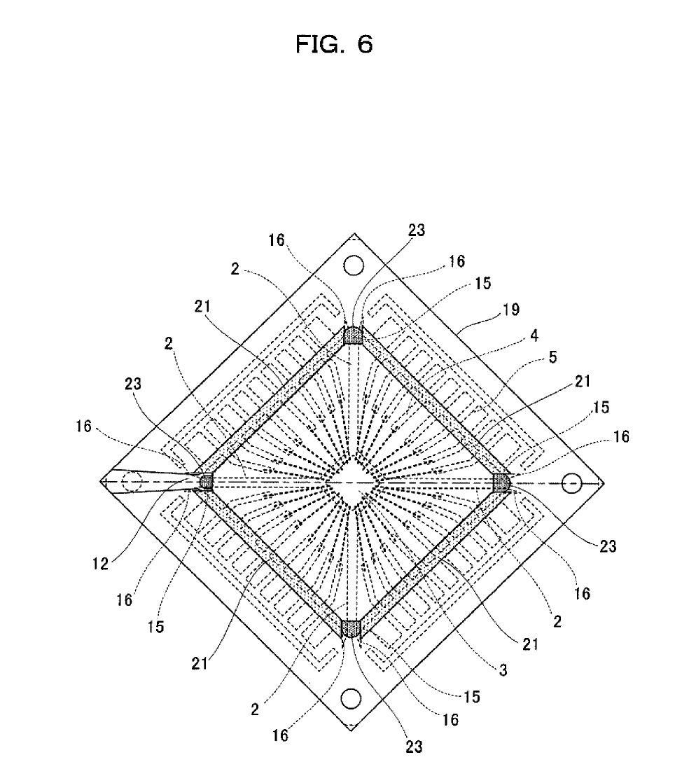

In the molding method using the molding die 38, as shown in FIG. 6, the lead frame 36 is set on the lower die body 19 and the upper die body 18 is moved down at a heating temperature. First, the outer periphery of the molding area 11 other than the support leads 2 is clamped by the upper die first clamping portions 20 and the lower die first clamping portions 21 (hereinafter, will be referred to as first clamping).

At this point, the support leads 2 are also expanded and distorted at the high temperature but the distortions of the support leads 2 in the molding area 11 are absorbed by the slits 16. Further, as shown in FIG. 7, in the state of the first clamping, the upper die second clamping portions 22 are moved down and the lower die second clamping portions 23 are moved up after a certain delay, so that the corners 15 are clamped by the upper die second clamping portions 22 and the lower die second clamping portions 23 (hereinafter, will be referred to as second clamping).

As described above, the second clamping is performed after the certain delay from the first clamping, so that the corners 15 are clamped after the support leads 2 are sufficiently expanded. Thus it is possible to reduce the distortions of the support leads 2 and an amount of die pad shift.

In other words, the lead frame 36 has a time lag in heat transfer and the long support leads 2 are thermally expanded even after the first clamping. Thus the second clamping is performed after the certain delay, that is, after the support leads 2 are sufficiently expanded, thereby reducing the distortions of the support leads 2. The certain delay substantially corresponds to a time period required for the sufficient thermal expansion of the support leads 2.

After that, the molding resin 13 is injected into the molding area 11 from an injection portion 12 and molding is performed.

### Second Embodiment

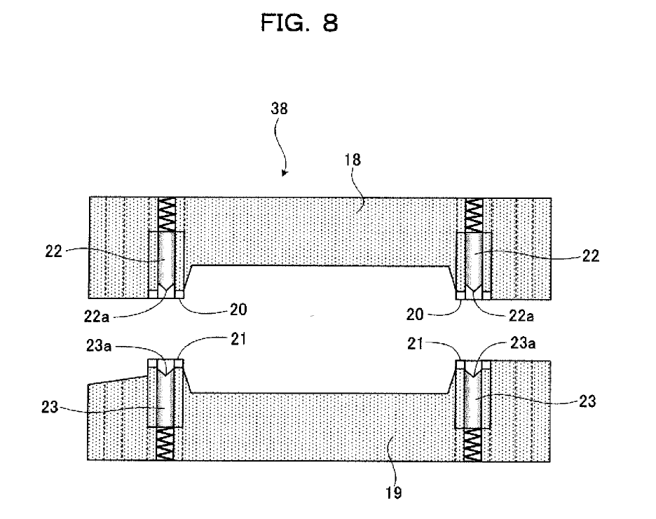

Referring to FIGS. 8 to 10, a second embodiment will be described below.

As shown in FIG. 8, upper die second clamping portions 22 have convex portions 22a (an example of a bend forming portion) on the lower ends. The convex portions 22a are pointed downward like the reverse of peaks. Further, lower die second clamping portions 23 have concave portions 23a (an example of the bend forming portion) on the upper ends. The concave portions 23a are recessed downward like valleys. When corners 15 are clamped by the upper die second clamping portions 22 and the lower die second clamping portions 23, the convex portions 22a and the concave portions 23a bend the corners 15 into V shapes.

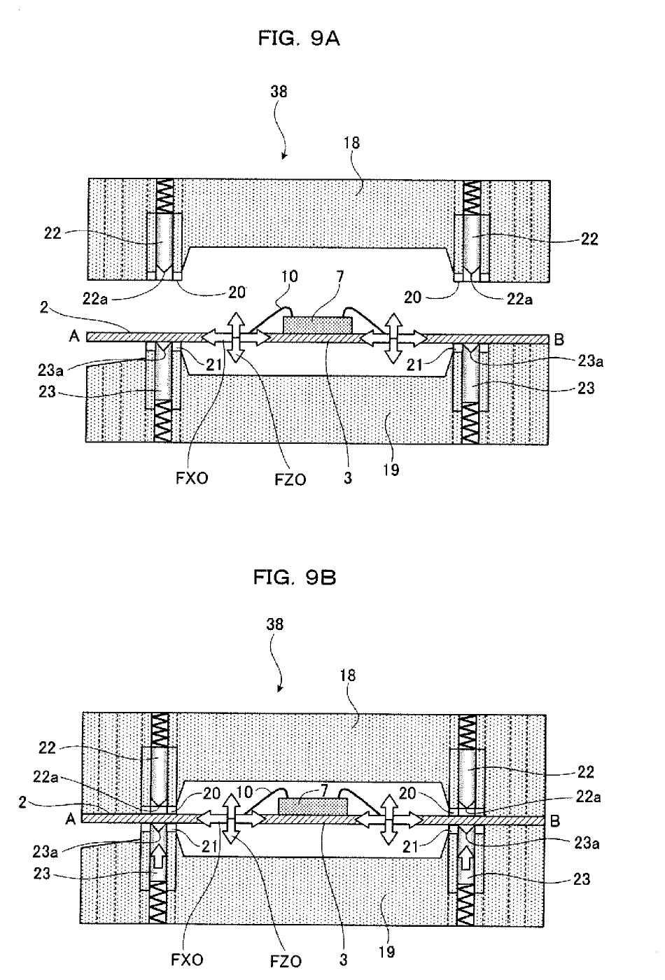

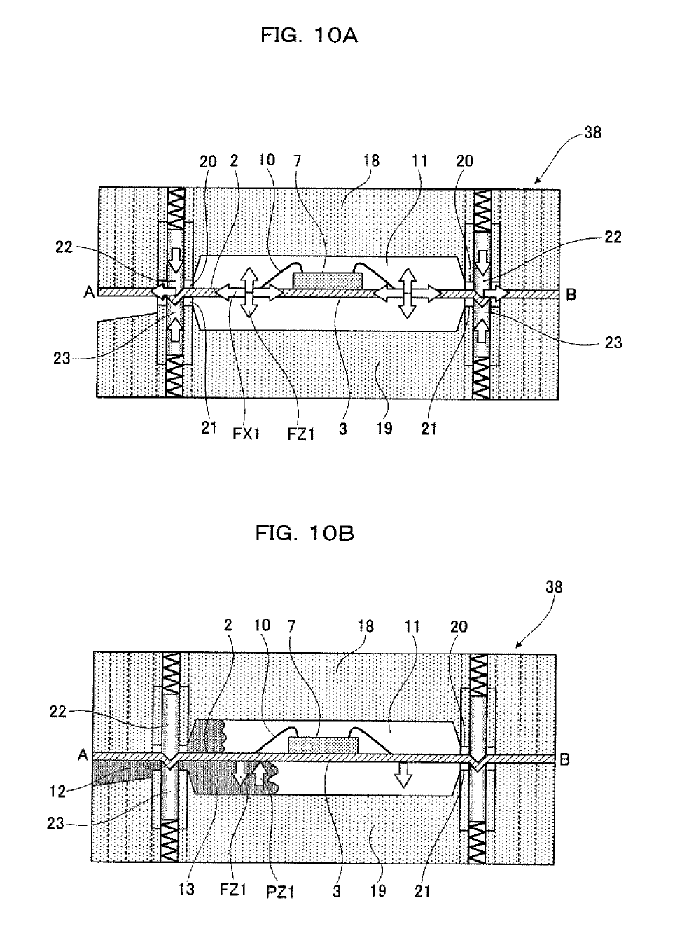

Referring to FIGS. 9A, 9B, 10A, and 10B, a molding method using a molding die 38 will now be described.

First, as shown in FIG. 9A, an upper die body 18 is moved up to open a mold and a lead frame 36 is set on a lower die body 19. In this state, the lead frame 36 is not clamped by the upper die body 18 and the lower die body 19, and support leads 2 have a tensile force of FX0 and a bearing force of FZ0 at this point.

Next, as shown in FIG. 9B, the upper die body 18 is moved down at a heating temperature, and then the outer periphery of a molding area 11 other than the support leads 2 is clamped by upper die first clamping portions 20 and lower die first clamping portions 21 (hereinafter, will be referred to as first clamping). At this point, the support leads 2 are not clamped and thus the tensile force of the support leads 2 is kept at FX0 and the bearing force of the support leads 2 is kept at FZ0. Further, the support leads 2 are also expanded and distorted at a high temperature but the distortions of the support leads 2 at this moment in the molding area 11 are absorbed by slits 16.

After that, as shown in FIG. 10A, in the state of the first clamping, the upper die second clamping portions 22 are moved down and the lower die second clamping portions 23 are moved up after a certain delay, so that the corners 15 are clamped by the upper die second clamping portions 22 and the lower die second clamping portions 23 (hereinafter, will be referred to as second clamping). At this points the convex portions 22a are fit into the concave portions 23a to bend the corners 15 into V shapes. Thus the tensile force of the support leads 2 increases from FX0 to FX1 (FX0<FX1) and the tensile force and the bearing force of the support leads 2 are in proportion to each other, so that the bearing force of the support leads 2 increases from FZ0 to FZ1 (FZ0<FZ1).

Thereafter, as shown in FIG. 10B, a molding resin 13 is injected into the molding area 11 from an injection portion 12. At this moment, an uneven resin flow generates a molding resin injection stress PZ1 in the vertical direction, and the molding resin injection stress PZ1 is applied to the support leads 2, a die pad 3, and a semiconductor chip 7. The bearing force of the support leads 2 increases from FZ0 to FZ1 as described above and the bearing force FZ1 is larger than the molding resin injection stress PZ1 (FZ1>PZ1), so that an amount of die pad shift can be reduced.

Next, the molding resin 13 is filled in the molding area 11 and the molding resin 13 in the molding area 11 is polymerized to complete postcure. After that, the upper die body 18 is moved up to release the first clamping of the upper die first clamping portions 20 and the lower die first clamping portions 21 and the second clamping of the upper die second clamping portions 22 and the lower die second clamping portions 23.

Thus the molding resin 13 changes from a gel state to a solid state and is connected to the support leads 2, the die pad 3, the semiconductor chip 7, and bonding wires 10. This connection does not cause a physical change exfoliating each interface, so that adhesion improves on the interface between the support leads 2 and the molding resin 13.

In the molding method using the molding die 38, the second clamping is performed after the certain delay from the first clamping, so that the corners 15 are clamped after the support leads 2 are sufficiently expanded. Thus it is possible to reduce the distortions of the support leads 2. Further, even when the support leads 2 are slightly distorted during the second clamping, the outer periphery of the molding area 11 other than the support leads 2 has been already clamped during the first clamping and thus it is possible to prevent the distortions of the support leads 2 from affecting the inner leads 4, outer leads 5, and tie bars 6.

In the second embodiment, the convex portions 22a are formed on the lower ends of the upper die second clamping portions 22 and the concave portions 23a are formed on the upper ends of the lower die second clamping portions 23. The concave portions 23a may be formed on the lower ends of the upper die second clamping portions 22 and the convex portions 22a may be formed on the upper ends of the lower die second clamping portions 23.

### Third Embodiment

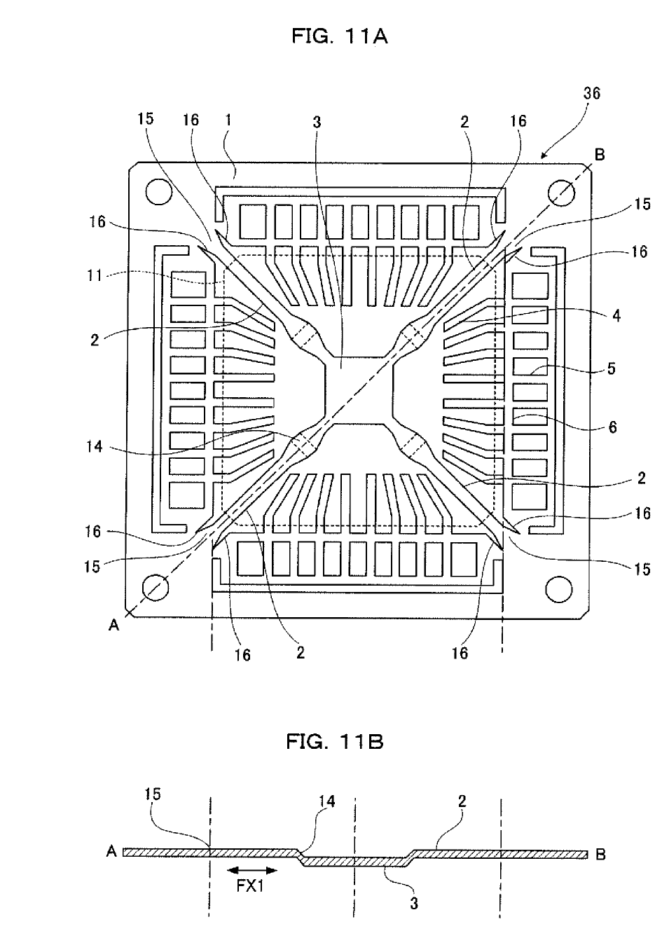

Referring to FIGS. 11A and 11B, a third embodiment will be described below.

FIG. 11A is a plan view showing a lead frame 36 of the third embodiment. FIG. 11B is a sectional view taken along line A-B of FIG. 11A.

A step 14 recessed downward is formed on a part of each support lead 2. The step 14 has a larger width than the support lead 2, except for a part including the step 14.

With this configuration, the formation of the step 14 can substantially equalize upper and lower resin thicknesses T on a semiconductor chip 7 and a die pad 3. Further, the step 14 increased in thickness have large stiffness. Thus even when a large tensile force FX1 is applied to the support leads 2, it is possible to prevent the deformation of the step 14 and keep the shapes of the step 14.

### Fourth Embodiment

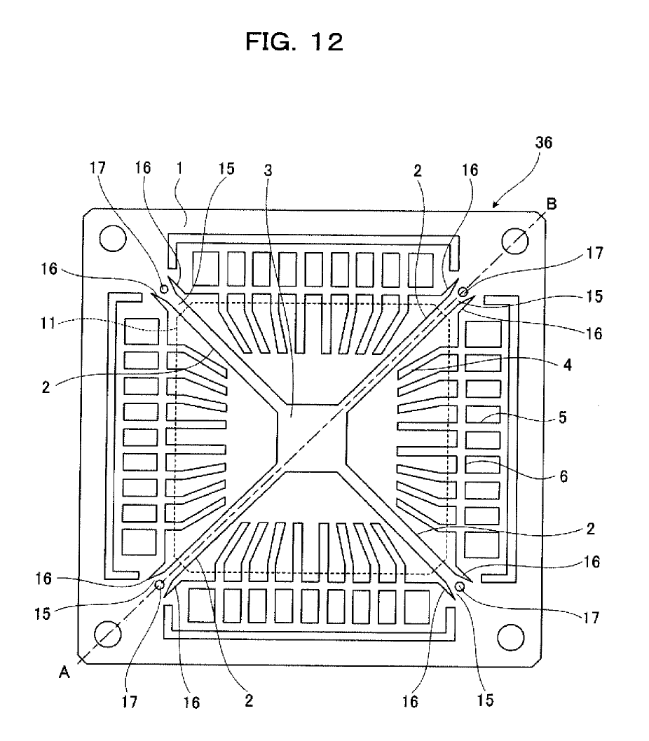

Referring to FIGS. 12 to 16, a fourth embodiment will be described below.

FIG. 12 is a plan view of a lead frame 36. In a frame 1, circular through holes 17 are formed on corners 15 disposed on the extension lines of the leading ends (one ends) of support leads 2.

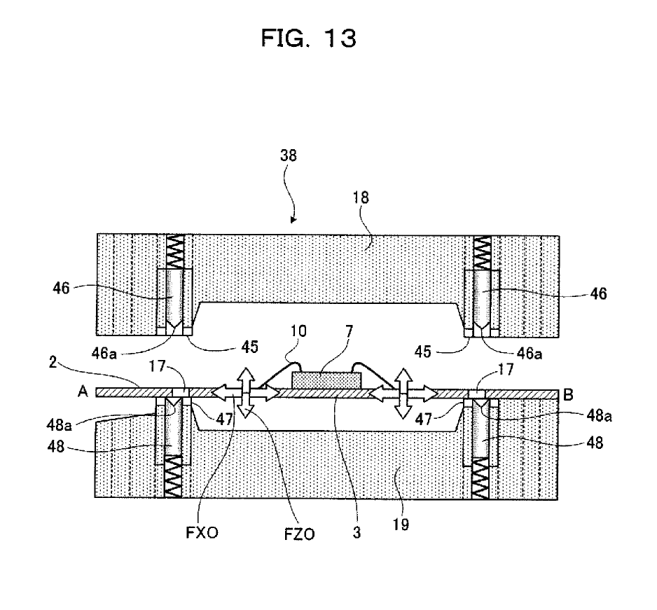

FIG. 13 is a sectional view of a molding die 38. An upper die body 18 (an example of one of die bodies) includes upper die clamping portions 45 for clamping the outer periphery of a molding area 11 other than the support leads 2, and upper die inserting members 46.

The upper die clamping portions 45 are fixed on the upper die body 18. The upper die inserting members 46 are built into the upper die body 18 so as to move in the vertical direction and are moved by a drive (not shown) in the vertical direction relative to the upper die body 18. The upper die inserting members 46 have convex portions 46a on the lower ends. The convex portions 46a are pointed downward like the reverse of peaks. The convex portions 46a of the upper die inserting members 46 can be inserted into and removed from the through holes 17 from the above of the through holes 17.

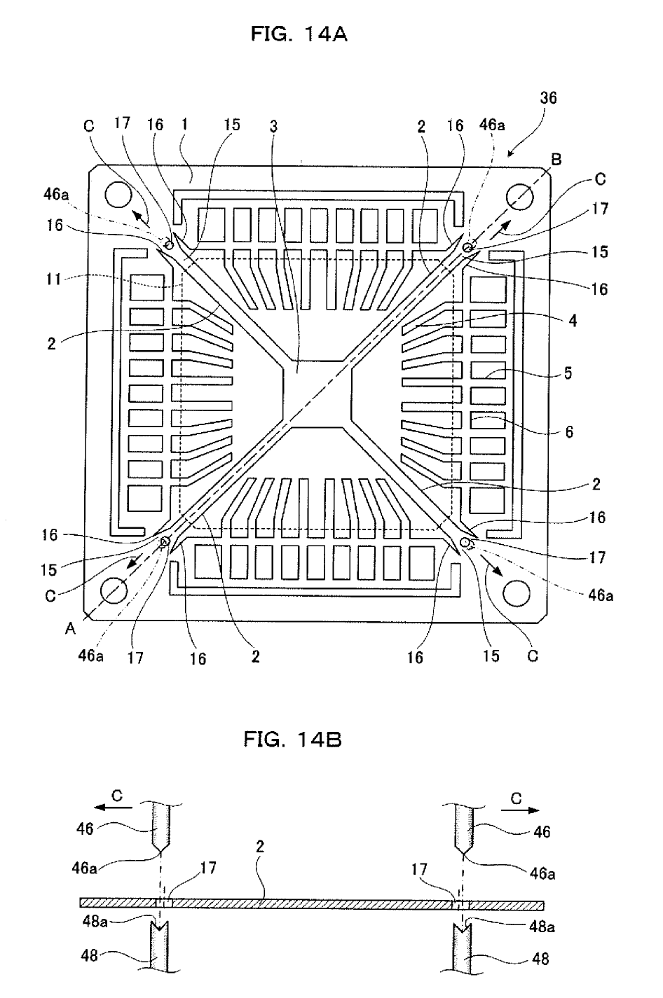

As shown in FIGS. 14A and 14B, relative to the positions of the through holes 17 when the support leads 2 are thermally expanded, the positions of the convex portions 46a are slightly displaced to outer sides C along the lengths of the support leads 2.

A lower die body 19 (an example of the other die body) includes lower die clamping portions 47 for clamping the outer periphery of the molding area 11 other than the support leads 2, and lower die receiving members 48 disposed below the upper die inserting members 46.

The lower die clamping portions 47 are fixed on the lower die body 19. The lower die receiving members 48 are built into the lower die body 19 so as to move in the vertical direction and are moved by the drive (not shown) in the vertical direction relative to the lower die body 19. The lower die receiving members 48 have concave portions 48a on the upper ends. The concave portions 48a are recessed downward like valleys. As shown in FIGS. 14A and 14B, like the positions of the convex portions 46a, the positions of the concave portions 48a are slightly displaced to the outer sides C relative to the positions of the through holes 17. The convex portions 46a of the upper die inserting members 46 can be fit into and removed from the concave portions 48a of the lower die receiving members 48 in the vertical direction.

In a molding method using the molding die 38, the upper die body 18 is moved down at a high temperature. First, the outer periphery of the molding area 11 other than the support leads 2 is clamped by the upper die clamping portions 45 and the lower die clamping portions 47. Thus the distortion of the frame 1 during clamping is dispersed without affecting the support leads 2.

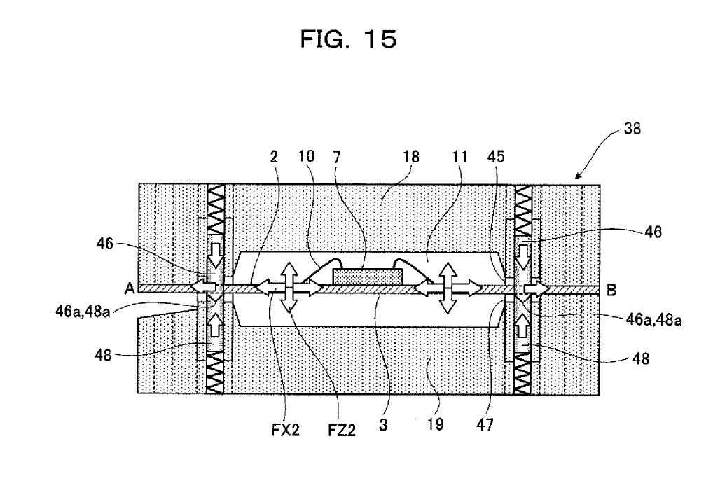

The support leads 2 are also expanded and distorted at a high temperature. At this moment, the distortions of the support leads 2 in the molding area 11 are absorbed by slits 16. In the clamping states after a certain delay, the upper die inserting members 46 are moved down and the lower die receiving members 48 are moved up as shown in FIG. 15. The convex portions 46a of the upper die inserting members 46 are inserted into the through holes 17 from the above, are hooked along the outer periphery of the frame 1, and are fit into the concave portions 48a of the lower die receiving members 48.

At this point, relative to the positions of the through holes 17 when the support leads 2 are thermally expanded, the positions of the convex portions 46a and the concave portions 48a are slightly displaced to the outer sides C as described above, so that the positions of the through holes 17 are slightly displaced to the outer sides C. Thus the tensile force of the support leads 2 increases from FX0 to FX2 (FX0<FX2) and the tensile force and the bearing force of the support leads 2 are in proportion to each other, so that the bearing force of the support leads 2 increases from FZ0 to FZ2 (FZ0<FZ2).

The tensile force FX0 is obtained when the support leads 2 are not clamped by the upper die inserting members 46 and the lower die receiving members 48. The bearing force FZ0 is obtained when the support leads 2 are not clamped by the upper die inserting members 46 and the lower die receiving members 48.

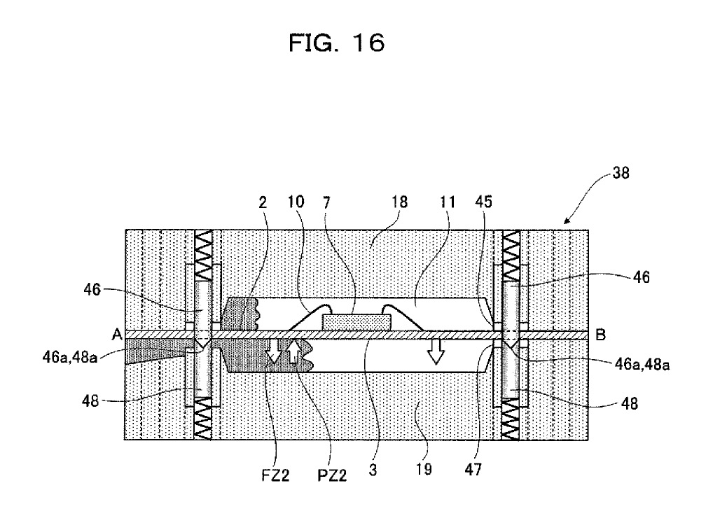

Thereafter, as shown in FIG. 16, a molding resin 13 is injected from an injection portion 12 to the molding area 11. At this point, an uneven resin flow generates a molding resin injection stress PZ2 in the vertical direction, and the molding resin injection stress PZ2 is applied to the support leads 2, a die pad 3, and a semiconductor chip 7. The bearing force of the support leads 2 increases from FZ0 to FZ2 as described above and the bearing force FZ2 is larger than the molding resin injection stress PZ2 (FZ2>PZ2), so that an amount of die pad shift can be reduced.

In the molding method using the molding die 38 configured thus, the outer periphery of the molding area 11 is clamped by the upper die clamping portions 45 and the lower die clamping portions 47, and then the convex portions 46a of the upper die inserting members 46 are inserted, after the certain delay, into the through holes 17 and are hooked, so that the outer periphery of the molding area 11 is clamped and the convex portions 46a are hooked after the support leads 2 are sufficiently expanded. Thus it is possible to reduce the distortions of the support leads 2. Further, even when the support leads 2 are slightly distorted during the hooking, the outer periphery of the molding area 11 other than the support leads 2 has been already clamped in the clamping of the upper die clamping portions 45 and the lower die clamping portions 47 and thus it is possible to prevent the distortions of the support leads 2 from affecting inner leads 4, outer leads 5, and tie bars 6.

The molding resin 13 is injected and filled into the molding area 11, and the molding resin 13 in the molding area 11 is polymerized to complete postcure. Thereafter, the upper die inserting members 46 are moved up, the lower die receiving members 48 are moved down, and the convex portions 46a of the upper die inserting members 46 are removed from the concave portions 48a of the lower die receiving members 48 and the through holes 17 on the corners 15 of the lead frame 36.

After that, the upper die body 18 is moved up to release the clamping of the upper die clamping portions 45 and the lower die clamping portions 47, and then the molded lead frame 36 is removed.

Thus the molding resin 13 changes from a gel state to a solid state and is connected to the support leads 2, the die pad 3, the semiconductor chip 7, and bonding wires 10. This connection does not cause a physical change exfoliating each interface, so that adhesion improves on the interface between the support leads 2 and the molding resin 13.

In the fourth embodiment, the upper die inserting members 46 including the convex portions 46a are provided on the upper die body 18, the lower die receiving members 48 including the concave portions 48a are provided on the lower die body 19, and the convex portions 46a of the upper die inserting members 46 can be inserted into and removed from the through holes 17. The present invention is not limited to this configuration. The upper die receiving members including the concave portions may be provided on the upper die body 18, the lower die inserting members including the convex portions may be provided on the lower die body 19, and the convex portions of the lower die inserting members may be inserted into and removed from the through holes 17.

### Fifth Embodiment

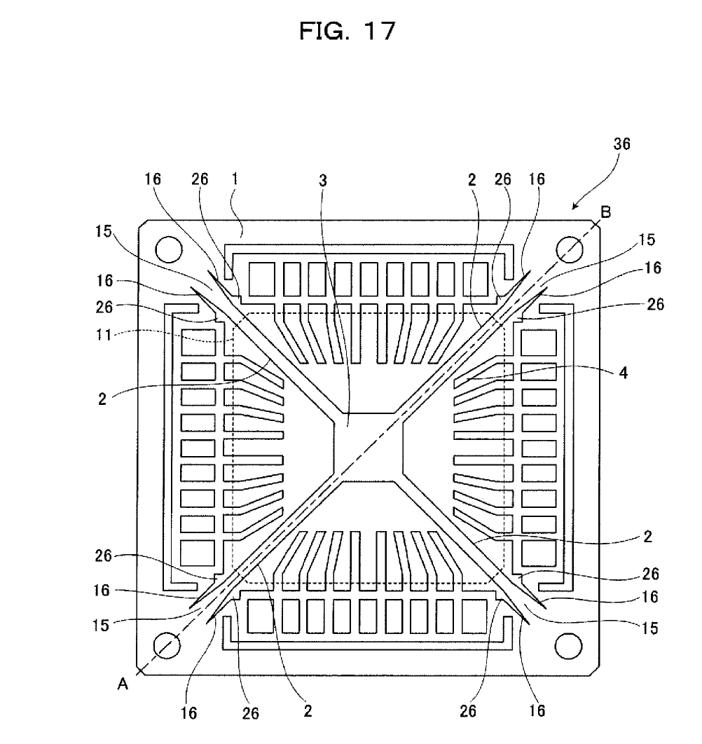

Referring to FIGS. 17 to 24, a fifth embodiment will be described below.

FIG. 17 is a plan view of a lead frame 36. In a frame 1, slits 16 are formed on both sides of corners 15 disposed on the extension lines of the leading ends of support leads 2. The slits 16 have notches 26 which extend from the slits 16 and are cut to the outside along the widths of the support leads 2.

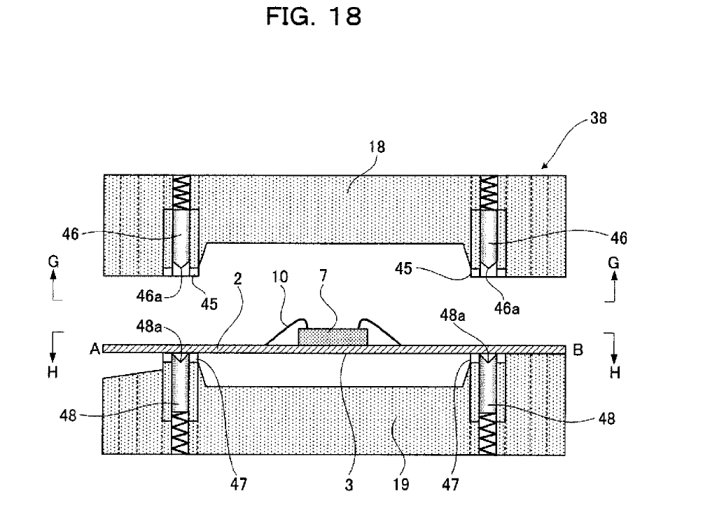

FIG. 18 is a sectional view of a molding die 38. An upper die body 18 (an example of one of die bodies) includes upper die clamping portions 45 for clamping the outer periphery of a molding area 11 other than the support leads 2, and upper die inserting members 46.

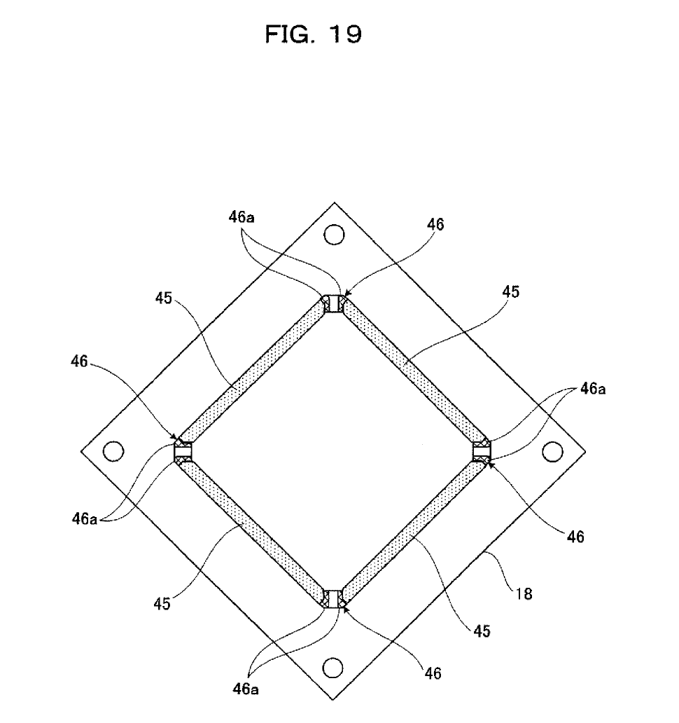

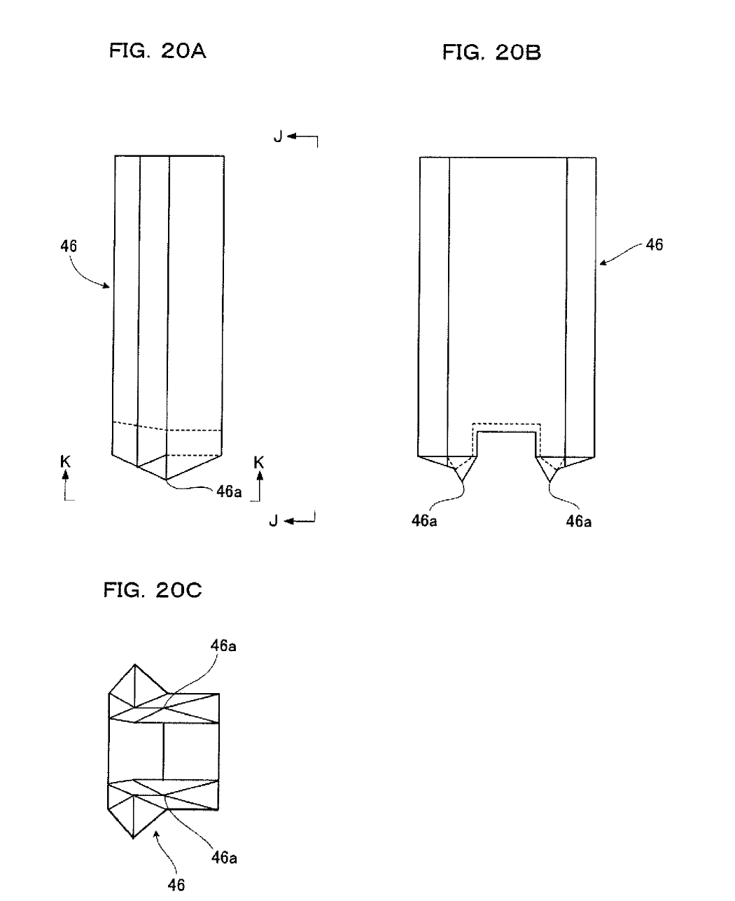

As shown in FIGS. 19 and 20A to 20C, the upper die clamping portions 45 are fixed on the upper die body 18. The upper die inserting members 46 are built into the upper die body 18 so as to move in the vertical direction and are moved by a drive (not shown) in the vertical direction relative to the upper die body 18. The upper die inserting members 46 each have a pair of convex portions 46a on the lower ends. The convex portions 46a are pointed downward like the reverse of peaks. The convex portions 46a can be inserted into and removed from the notches 26 from the above of the notches 26.

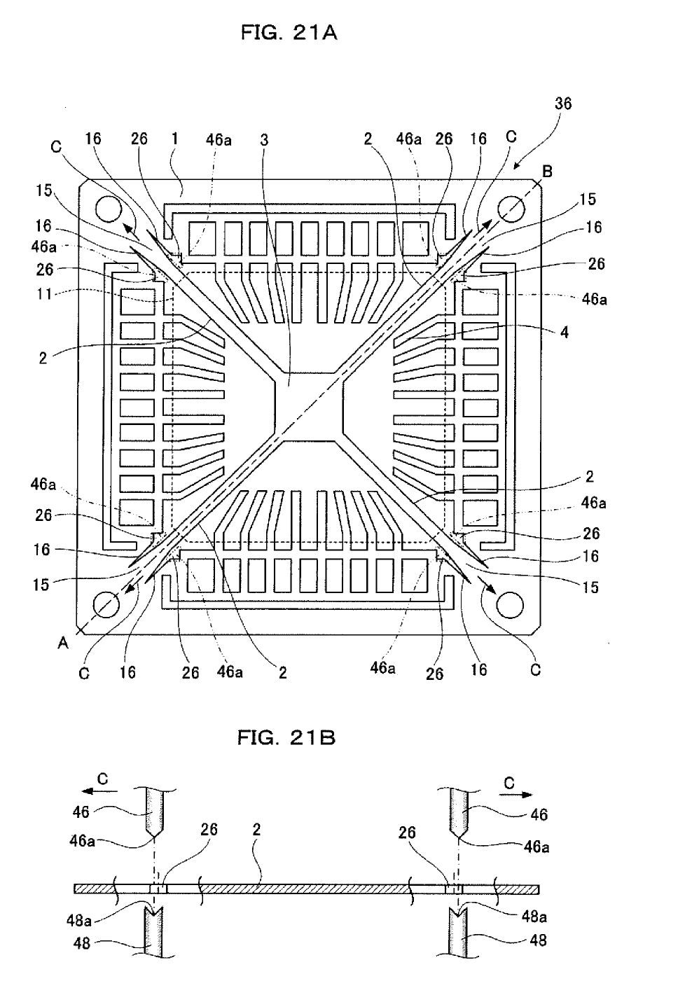

As shown in FIGS. 21A and 21B, relative to the positions of the notches 26 when the support leads 2 are thermally expanded, the positions of the convex portions 46a are slightly displaced to outer sides C along the lengths of the support leads 2.

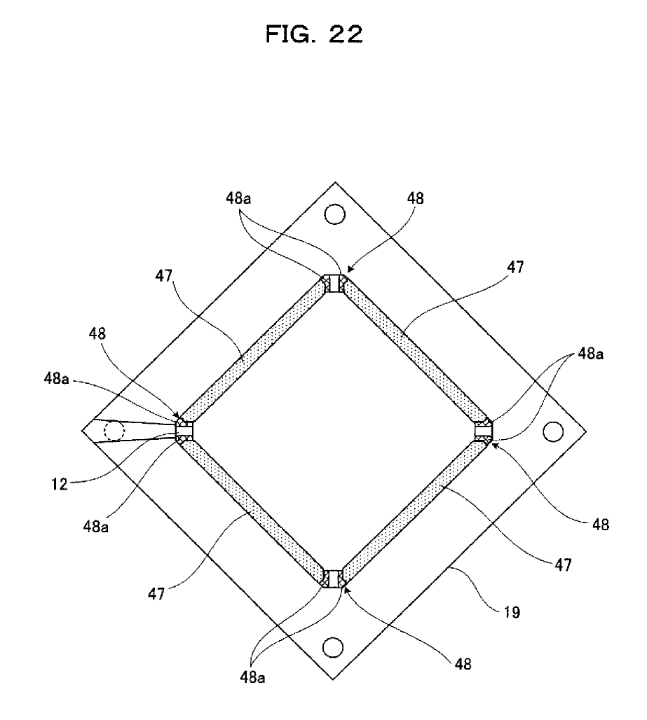

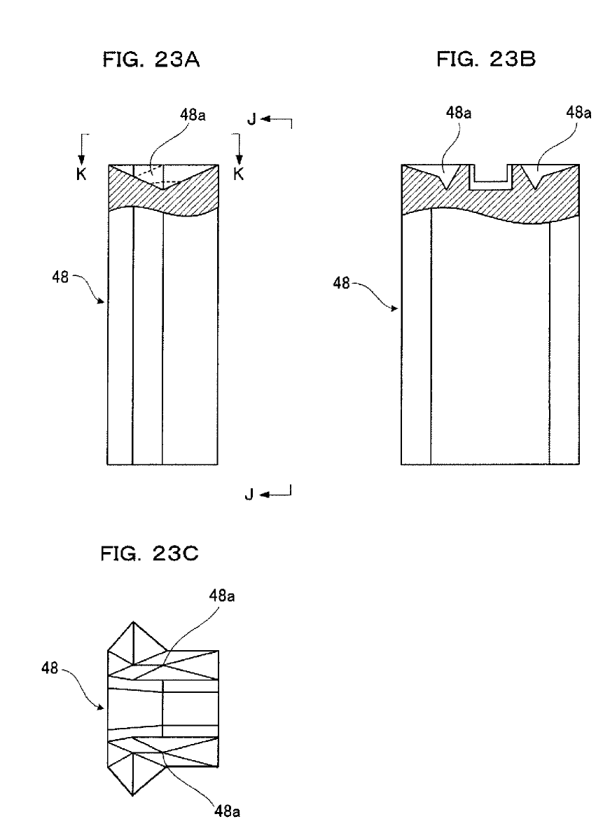

As shown in FIGS. 22 and 23A to 23C, a lower die body 19 (an example of the other die body) includes lower die clamping portions 47 for clamping the outer periphery of the molding area 11 other than the support leads 2, and lower die receiving members 48 disposed below the upper die inserting members 46.

The lower die clamping portions 47 are fixed on the lower die body 19. The lower die receiving members 48 are built into the lower die body 19 so as to move in the vertical direction and are moved by the drive (not shown) in the vertical direction relative to the lower die body 19. The lower die receiving members 48 each have a pair of concave portions 48a on the upper ends. The concave portions 48a are recessed downward like valleys. As shown in FIGS. 21A and 21B, like the positions of the convex portions 46a, the positions of the concave portions 48a are slightly displaced to the outer sides C relative to the positions of the notches 26.

The convex portions 46a of the upper die inserting members 46 can be fit into and removed from the concave portions 48a of the lower die receiving members 48 in the vertical direction.

In a molding method using the molding die 38, the upper die body 18 is moved down at a high temperature. First, the outer periphery of the molding area 11 other than the support leads 2 is clamped by the upper die clamping portions 45 and the lower die clamping portions 47. Thus the distortion of the frame 1 during clamping is dispersed without affecting the support leads 2.

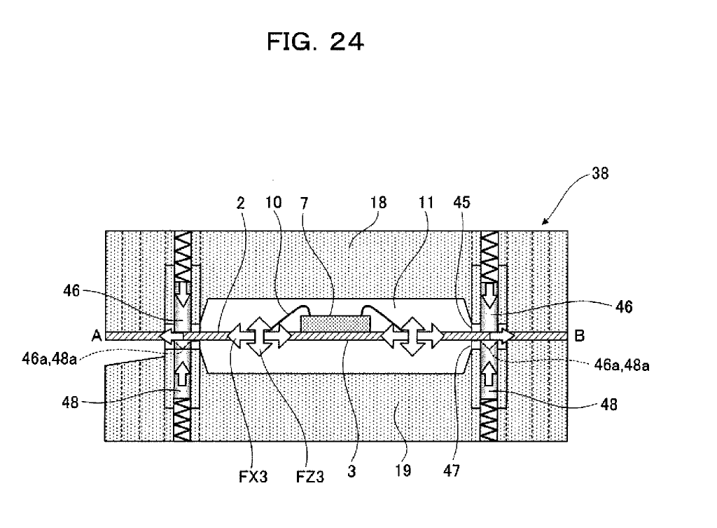

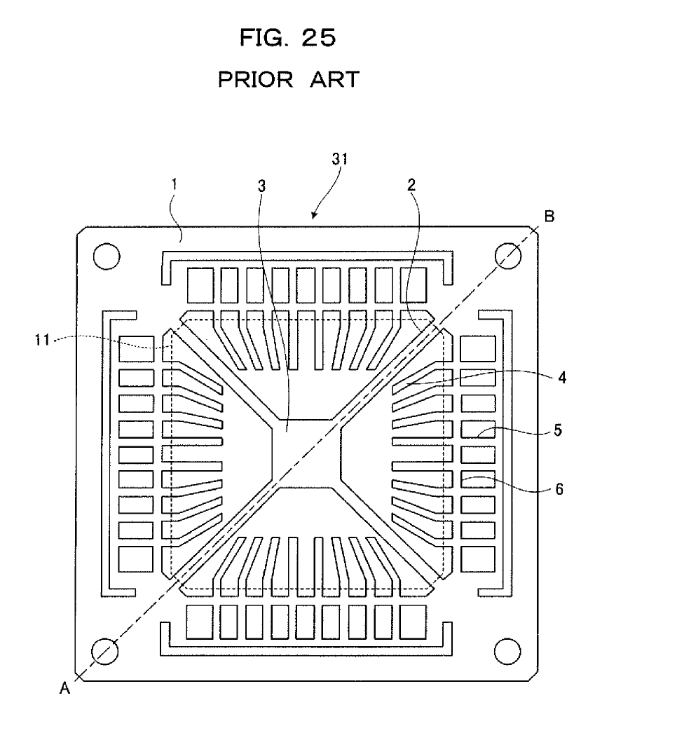

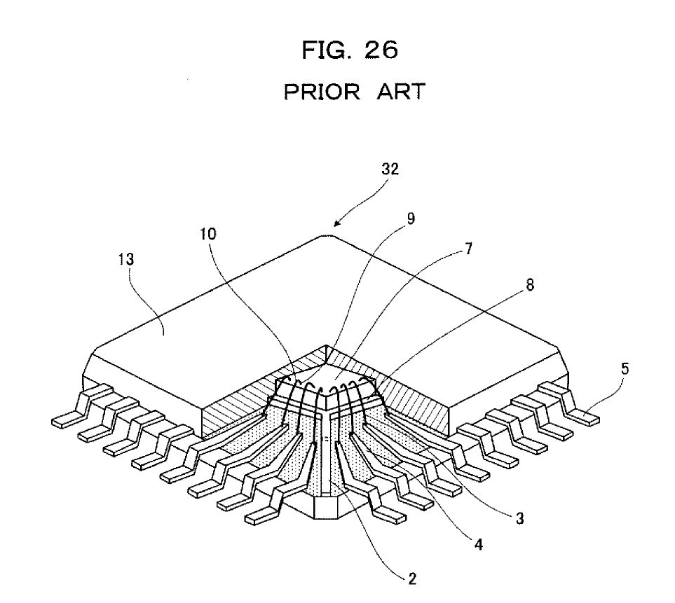

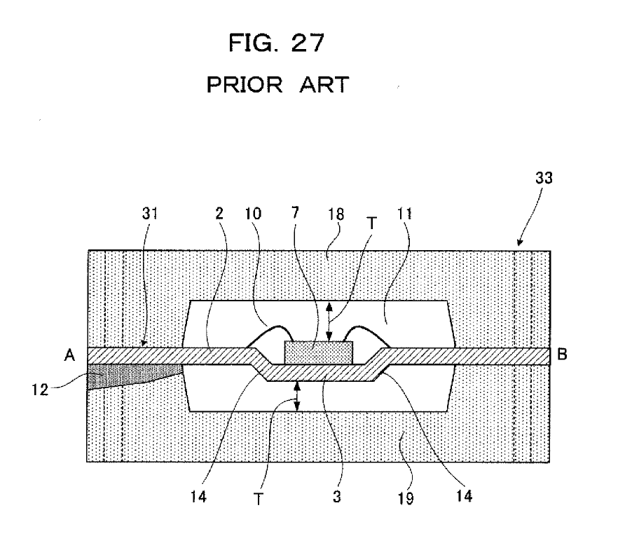

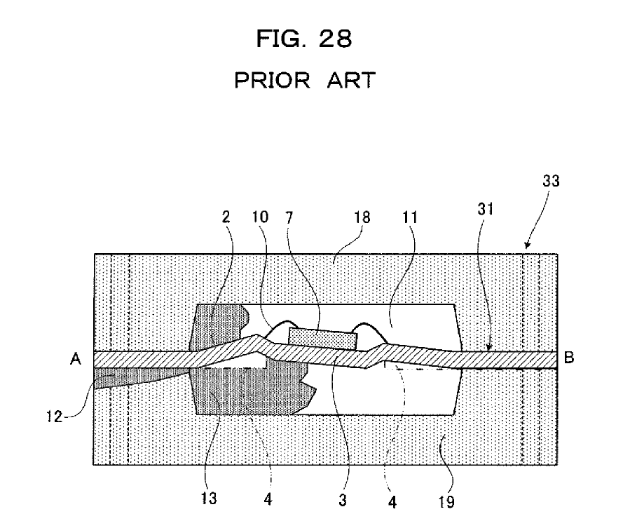

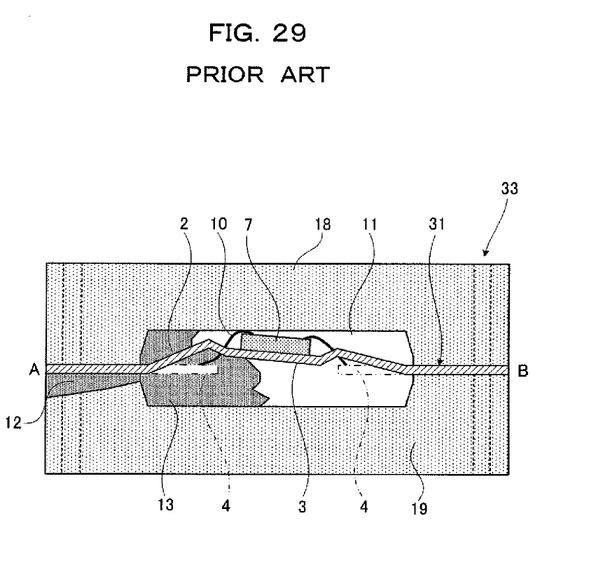

The support leads 2 are also expanded and distorted at a high temperature. At this moment, the distortions of the support leads 2 in the molding area 11 are absorbed by the slits 16. In the clamping state, after a certain delay, the upper die inserting members 46 are moved down and the lower die receiving members 48 are moved up as shown in FIG. 24. The convex portions 46a of the upper die inserting members 46 are inserted into the notches 26 from the above, are hooked along the outer periphery of the frame 1, and are fit into the concave portions 48a of the lower die receiving members 48.

At this point, relative to the positions of the notches 26 when the support leads 2 are thermally expanded, the positions of the convex portions 46a and the concave portions 48a are slightly displaced to the outer sides C as described above, so that the positions of the notches 26 are slightly displaced to the outer sides C. Thus the tensile force of the support leads 2 increases from FX0 to FX3 (FX0<FX3) and the tensile force and the bearing force of the support leads 2 are in proportion to each other, so that the bearing force of the support leads 2 increases from FZ0 to FZ3 (FZ0<FZ3).

The tensile force FX0 is obtained when the support leads 2 are not clamped by the upper die inserting members 46 and the lower die receiving members 48. The bearing force FZ0 is obtained when the support leads 2 are not clamped by the upper die inserting members 46 and the lower die receiving members 48.

Thereafter, a molding resin 13 is injected from an injection portion 12 to the molding area 11 At this point, an uneven resin flow generates a molding resin injection stress PZ3 (not shown) in the vertical direction, and the molding resin injection stress PZ3 is applied to the support leads 2, a die pad 3, and a semiconductor chip 7. The bearing force of the support leads 2 increases from FZ0 to FZ3 as described above and the bearing force FZ3 is larger than the molding resin injection stress PZ3 (FZ3>PZ3), so that an amount of die pad shift can be reduced.

Further, in a state in which the convex portions 46a of the upper die inserting members 46 are inserted into the notches 26 and are fit into the concave portions 48a of the lower die receiving members 48, the convex portions 46a are not disposed on the corners 15 on the leading ends of the support leads 2 but are disposed on both sides of the corners 15 as shown in FIG. 21A Thus as shown in FIG. 22, the injection portion 12 is formed like a straight line, so that the molding resin 13 can smoothly flow through the injection portion 12 when injected. Consequently, it is possible to suppress a turbulent flow of resin and reduce external voids, internal voids, exfoliation, or bonding wire sweep in the molding area 11

In the molding method using the molding die 38, the outer periphery of the molding area 11 is clamped by the upper die clamping portions 45 and the lower die clamping portions 47, and then the convex portions 46a of the upper die inserting members 46 are inserted, after the certain delay, into the notches 26 and hooked, so that the outer periphery of the molding area 11 is clamped and the convex portions 46a are hooked after the support leads 2 are sufficiently expanded. Thus it is possible to reduce the distortions of the support leads 2. Further, even when the support leads 2 are slightly distorted during the hooking, the outer periphery of the molding area 11 other than the support leads 2 has been already clamped in the clamping of the upper die clamping portions 45 and the lower die clamping portions 47 and thus it is possible to prevent the distortions of the support leads 2 from affecting inner leads 4, outer leads 5, and tie bars 6.

The molding resin 13 is injected and filled into the molding area 11, and the molding resin 13 in the molding area 11 is polymerized to complete postcure, Thereafter, the upper die inserting members 46 are moved up, the lower die receiving members 48 are moved down, and the convex portions 46a of the upper die inserting members 46 are removed from the concave portions 48a of the lower die receiving members 48 and the notches 26 of the slits 16.

After that, the upper die body 18 is moved up to release the clamping of the upper die clamping portions 45 and the lower die clamping portions 47, and then the molded lead frame 36 is removed.

Thus the molding resin 13 changes from a gel state to a solid state and is connected to the support leads 2, the die pad 3, the semiconductor chip 7, and bonding wires 10. This connection does not cause a physical change exfoliating each interface, so that adhesion improves on the interface between the support leads 2 and the molding resin 13.

In the fifth embodiment, the upper die inserting members 46 including the pairs of the convex portions 46a are provided on the upper die body 18, the lower die receiving members 48 including the pairs of the concave portions 48a are provided on the lower die body 19, and the convex portions 46a of the upper die inserting members 46 can be inserted into and removed from the notches 26. The present invention is not limited to this configuration. The upper die receiving members including the pairs of the concave portions may be provided on the upper die body 18, the lower die inserting members including the pairs of the convex portions may be provided on the lower die body 19, and the convex portions of the lower die inserting members may be inserted into and removed from the notches 26.

In the fourth and fifth embodiments, a step 14 may be formed on a part of the support lead 2 as in the third embodiment.

In the first to fifth embodiments, the lead frame 36 is a single lead frame for a single semiconductor device. The lead frame 36 may be a matrix frame for semiconductor devices arranged in multiple rows and columns.

In the first, second, fourth, and fifth embodiments, the molding die 38 is a molding die for a single semiconductor device. The molding die 38 may be a molding die for collectively performing molding on semiconductor devices and the lead frames 36 arranged in multiple rows and columns.

In the first, second, fourth, and fifth embodiments, the semiconductor chip 7 having a single layer is mounted. A semiconductor chip having two or more layers may be mounted.

As described above, the lead frame, the molding die, and the molding method of the present invention have the effect of reducing the distortions of the frame and the support leads and increasing the bearing force of the support leads when a semiconductor device is molded. Thus the present invention is useful as a lead frame, a molding die, and a molding method for reducing a shift of a die pad and a semiconductor chip during the injection of molding resin.

1. A lead frame, comprising:
a frame;
support leads having leading ends connected to an inner side of the frame;
a die pad connected to terminal ends of the support leads;
a plurality of inner leads radially arranged at a predetermined spacing from the die pad;
outer leads extended from the inner leads and connected to the inner side of the frame; and
tie bars disposed on boundaries of the inner leads and the outer leads to connect the adjacent leads,
the lead frame having the inner leads, the terminals ends of the support leads, and the die pad in a molding area, and
the lead frame having the frame, the leading ends of the support leads, the outer leads, and the tie bars outside the molding area,
wherein the lead frame further comprises slits formed on both sides of corners disposed on extension lines of the leading ends of the support leads in the frame.

2. The lead frame according to claim 1, further comprising holes formed on the corners disposed on the extension lines of the leading ends of the support leads in the frame.

3. The lead frame according to claim 1, further comprising notches extended from the slits and cut to outside along widths of the support leads.

4. The lead frame according to claim 1, further comprising a step formed on the support lead,
wherein the step of the support lead is larger in width than a part other than the step of the support lead.

5. A molding die used for clamping the lead frame according to claim 1 and molding the lead frame with resin, the molding die comprising an upper die body and a lower die body, the upper and lower die bodies comprising:
upper die and lower die first clamping portions for clamping an outer periphery of the molding area other than the support leads; and
upper die and lower die second clamping portions for clamping the corners disposed on the extension lines of the leading ends of the support leads in the frame,
wherein the upper die first clamping portions are fixed on the upper die body,
the upper die second clamping portions are movable in a vertical direction relative to the upper die body,
the lower die first clamping portions are fixed on the lower die body, and
the lower die second clamping portions are movable in the vertical direction relative to the lower die body.

6. The molding die according to claim 5, wherein the upper die second clamping portion and the lower die second clamping portion each have a bend forming portion for bending the corner.

7. A molding die used for clamping the lead frame according to claim 2 and molding the lead frame with resin, the molding die comprising an upper die body and a lower die body, the upper and lower die bodies comprising upper die and lower die clamping portions for clamping an outer periphery of the molding area other than the support leads;
wherein the upper die clamping portions are fixed on the upper die body,
the lower die clamping portions are fixed on the lower die body,
one of the upper die body and the lower die body comprises die inserting members movable in a vertical direction,
the other die body comprises die receiving members movable in the vertical direction,
the die inserting member has a convex portion,
the die receiving member has a concave portion,
the convex portions can be inserted into and removed from the holes on the corners and can be fit into and removed from the concave portions, and
positions of the convex portions are, relative to positions of the holes when the support leads are thermally expanded, displaced to outside along lengths of the support leads,

8. A molding die used for clamping the lead frame according to claim 3 and molding the lead frame with resin, the molding die comprising an upper die body and a lower die body, the upper and lower die bodies comprising upper die and lower die clamping portions for clamping an outer periphery of the molding area other than the support leads;
wherein the upper die clamping portions are fixed on the upper die body,
the lower die clamping portions are fixed on the lower die body,
one of the upper die body and the lower die body comprises die inserting members movable in a vertical direction,
the other die body comprises die receiving members movable in the vertical direction,
the die inserting member has a pair of convex portions,
the die receiving member has a pair of concave portions,
the convex portions can be inserted into and removed from the notches of the slits and can be fit into and removed from the concave portions, and
positions of the convex portions are, relative to positions of the notches when the support leads are thermally expanded, displaced to outside along lengths of the support leads.

9. A molding method for molding the lead frame with resin by means of the molding die according to claim 5, comprising the steps of:
clamping the outer periphery of the molding area other than the support leads of the lead frame by means of the upper die first clamping portions and the lower die first clamping portions;
clamping, after a certain delay in this state, the corners disposed on the extension lines of the leading ends of the support leads in the frame of the lead frame, by means of the upper die second clamping portions and the lower die second clamping portions; and
injecting a molding resin into the molding area from an injection portion to mold the lead frame.

10. A molding method for molding the lead frame with resin by means of the molding die according to claim 6, comprising the steps of:
clamping the outer periphery of the molding area other than the support leads of the lead frame by means of the upper die first clamping portions and the lower die first clamping portions;
clamping, after a certain delay in this state, the corners disposed on the extension lines of the leading ends of the support leads in the frame of the lead frame and bending the corners by means of the upper die second clamping portions and the lower die second clamping portions; and
injecting a molding resin into the molding area from an injection portion to mold the lead frame.

11. A molding method for molding the lead frame with resin by means of the molding die according to claim 7, comprising the steps of:
clamping the outer periphery of the molding area other than the support leads of the lead frame by means of the upper die clamping portions and the lower die clamping portions;
inserting, after a certain delay in this state, the convex portions of the die inserting members into the holes on the corners of the lead frame and fitting the convex portions into the concave portions of the die receiving members; and
injecting a molding resin into the molding area from an injection portion to mold the lead frame.

12. The molding method according to claim 11, wherein the molding resin is injected and filled into the molding area, the molding resin in the molding area is polymerized to complete posture, the convex portions of the die inserting members are removed from the concave portions of the die receiving members and are removed from the holes on the corners of the lead frame,
clamping of the upper die clamping portions and the lower die clamping portions is released, and then the molded lead frame is removed.

13. A molding method for molding the lead frame with resin by means of the molding die according to claim 8, comprising the steps of:
clamping the outer periphery of the molding area other than the support leads of the lead frame by means of the upper die clamping portions and the lower die clamping portions;
inserting, after a certain delay in this state, the convex portions of the die inserting members into the notches of the slits of the lead frame and fitting the convex portions into the concave portions of the die receiving members; and
injecting a molding resin into the molding area from an injection portion to mold the lead frame.

14. The molding method according to claim 13, wherein the molding resin is injected and filled into the molding area, the molding resin in the molding area is polymerized to complete postcure, the convex portions of the die inserting members are removed from the concave portions of the die receiving members and are removed from the notches of the slits of the lead frame,
clamping of the upper die clamping portions and the lower die clamping portions is released, and then the molded lead frame is removed.
